(19) United States
(12) Patent Application Publication
(10) Pub. No.: US 2008/0160762 A1
(43) Pub. Date: Jul. 3, 2008

(54) METHOD FOR THE PROTECTION OF METAL LAYERS AGAINST EXTERNAL CONTAMINATION

(76) Inventors: Frank Feustel, Dresden (DE); Thomas Werner, Moritzburg (DE); Kai Frohberg, Niederau (DE)

Correspondence Address: J. Mike Amerson;Williams, Morgan & Amerson, P.C., Suite 1100, 10333 Richmond, Houston, TX, 77042, US

(21) Appl. No.: 11/778,291

(22) Filed: Jul. 16, 2007

(30) Foreign Application Priority Data
Dec. 29, 2006 (DE) 10 2006 062 032.1

(51) Int. Cl. H01L 21/443

(52) U.S. Cl. 438/680; 257/E21.478

(57) ABSTRACT

In order to avoid the contamination of a seed layer, which is typically highly reactive with the external atmosphere, during the formation of interconnect structures in a semiconductor device, a protective layer is formed. The protective layer may be comprised of oxide formed in an oxidizing ambient prior to transporting the semiconductor device to a subsequent process tool.

### BACKGROUND OF THE INVENTION

1. Field of the Invention

The present disclosure generally relates to the field of fabrication of integrated circuits, and, more particularly, to the protection of metal layers, formed above a patterned dielectric material comprising trenches and vias, against external contamination.

2. Description of the Related Art

In an integrated circuit, a large number of circuit elements, such as transistors, capacitors, resistors and the like, are formed in or on an appropriate substrate, usually in a substantially planar configuration. Due to the large number of circuit elements and the required complex layout of the integrated circuits, generally the electrical connection of the individual circuit elements may not be established within the same level on which the circuit elements are manufactured, but requires one or more additional “wiring” layers, also referred to as metallization layers. These metallization layers generally include metal-containing lines providing the inner-level electrical connection and also include a plurality of inter-level connections, also referred to as vias, filled with an appropriate metal and providing the electrical connection between two neighboring stacked metallization layers, wherein the metal-containing lines and vias may also be commonly referred to as interconnect structures.

Due to the continuous shrinkage of the feature sizes of circuit elements in modern integrated circuits, the number of circuit elements for a given chip area, that is the packing density, also increases, thereby requiring an even larger increase in the number of electrical interconnections to provide the desired circuit functionality. Therefore, the number of stacked metallization layers usually increases as the number of circuit elements per chip area becomes larger. The fabrication of a plurality of metallization layers entails extremely challenging issues to be solved, such as mechanical, thermal and electrical reliability of a plurality of stacked metallization layers that may be employed in sophisticated microprocessors. Semiconductor manufacturers are increasingly replacing the well-known metallization metal aluminum with a metal that allows higher current densities and hence allows a reduction in the dimensions of the interconnections and thus the number of stacked metallization layers. For example, copper and alloys thereof are materials used for replacing aluminum due to their superior characteristics in view of higher resistance against electro-migration and significantly lower electrical resistivity when compared with aluminum. Despite these advantages, copper also exhibits a number of disadvantages regarding the processing and handling of copper in a semiconductor facility. For instance, copper may not be efficiently applied onto a substrate in larger amounts by well-established deposition methods, such as chemical vapor deposition (CVD), and also may not be effectively patterned by the usually employed anisotropic etch procedures. Consequently, in manufacturing metallization layers including copper, the so-called damascene or inlaid technique (single and dual) is preferably used, wherein a dielectric layer is first applied and then patterned to receive trenches and vias, which are subsequently filled with a copper-based metal. A further major drawback of the use of copper is its propensity to readily diffuse in many dielectric materials, such as silicon dioxide, which is a well-established and approved dielectric material in fabricating integrated circuits.

It is therefore necessary to employ a so-called barrier material in combination with a copper-based metallization to substantially avoid diffusion of dielectrics into the copper, thereby negatively modifying its electric characteristics, and also reduce any diffusion of copper into the surrounding dielectric material, as copper may readily migrate to sensitive semiconductor areas, thereby significantly changing the characteristics thereof. The barrier material provided between the copper and the dielectric material should, however, in addition to the required barrier characteristics, exhibit good adhesion to the dielectric material as well as to the copper to impart superior mechanical stability to the interconnect and should also have as low an electrical resistance as possible so as to not unduly compromise the electrical properties of the interconnection.

With reference to FIGS. 1a-1c, a typical process technique for the fabrication of sophisticated copper-based integrated circuits will be described. FIG. 1a depicts a schematic cross-sectional view of a semiconductor structure 100 comprising a substrate 101, for example, a semiconductor substrate bearing a plurality of individual circuit elements (not shown), such as transistors, resistors, capacitors and the like. The substrate 101 is representative of any type of appropriate substrate with or without any additional circuit elements and may, in particular, represent sophisticated integrated circuit substrates having included therein circuit elements with critical feature sizes in the deep submicron range. A first dielectric layer 102 is formed above the substrate 101 and presents a trench or through hole 105 in order to form an interconnection or via structure. The trench 105 is coated by a barrier layer 103 and a seed layer 104.

The barrier layer 103 may be comprised of tantalum (Ta) and/or tantalum nitride (TaN) or other materials which can substantially prevent the diffusion of the conductive metal into the dielectric material 102. The seed layer 104 typically comprises copper (Cu), copper alloys, silver, tungsten or any other appropriate conductive material appropriate for seeding a subsequent electrochemical deposition process.

The structure 100 may be formed on the basis of well-established techniques. In particular, the barrier layer 103 may be formed using physical vapor deposition (PVD), such as sputtering, or chemical vapor deposition (CVD), such as atomic vapor deposition (ALD). The seed layer 104 may be formed on the basis of PVD, CVD, electroless plating and the like.

After the deposition of the seed layer 104 and barrier layer 103, the substrate 101 has to undergo further fabrication processes. Typically, the interconnection/via structure 105 has to be filled with a metal component. For this purpose, electroplating has proven to be a viable deposition technique with respect to throughput and fill capabilities. The substrate 101 therefore has to be conveyed from the deposition tool used for forming the barrier layer 103 and/or the seed layer 104 to an electroplating tool.

FIG. 2 schematically depicts the different process tools which are needed in order to fill the interconnection or via structure in a substrate. The seed layer deposition is typically performed under vacuum conditions inside a deposition tool 201. When the deposition is completed, the substrate 101 enters a load lock chamber 202 with a nitrogen (N₂) rich or any other inert atmosphere before leaving the deposition tool 201. The load lock chamber 202 separates a deposition chamber 204 from the clean room environment, thereby substantially avoiding possible contamination of the deposition chamber 204 with external contaminants, such as humidity and the like. When the substrate 101 exits the deposition tool 201, a transportation system 203 is used to move the substrate 101 to the next process tool, which is typically an electroplating tool 205. In the electroplating tool 205, the interconnection structures of the substrate are filled with a conductive material, typically comprising copper (Cu).

During transportation, the substrate 101 may come into contact with ambient air of the clean room, even if sophisticated transport containers may be used, thereby contaminating the seed layer 104. Copper is a highly reactive metal and, when exposed to the ambient air, oxide regions may be formed on different parts of the seed layer 104 or other reactions may take place between the seed layer 104 and elements present in the air.

FIG. 1b schematically depicts the semiconductor structure 100 when coming into contact with air 106 in the clean room. The profile or surface of the seed layer 104 may become rough, due to the formation of oxide regions, pitting corrosion and other reactions which take place on the seed layer surface. This modified surface of the seed layer 104 may give rise to defects during the electrochemical filling in of the metal for the interconnection/via structure.

FIG. 1c schematically depicts the semiconductor structure 100 after the electroplating process. Above the seed layer 104, a metal layer 107 has been formed, which may comprise copper or copper alloys. The irregular shape of the seed layer 104 and the presence of contamination elements may cause a reduced quality at the interface to the metal layer 107. For example, voids and dislocations 108 may occur, as shown in FIG. 1c, which can severely reduce the performance of the interconnection/via structures.

The present disclosure is directed to various methods that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure relates in a general way to a method of protecting a conductive layer of a semiconductor structure against external contamination. In some aspects, the present disclosure relates to the protection of seed layers in interconnection or via structures against external contamination. For example, copper (Cu) or copper-related seed layers may be efficiently protected from external contamination by protection layers which are formed on the seed layers. In some illustrative embodiments, the protection layers are oxide layers, such as copper oxide layers. The oxide layers may be fabricated in a controlled way and may have a predetermined known thickness. Moreover, the oxide layer may protect the seed layer from ambient air when the semiconductor structure is transported from a deposition tool to the subsequent process tool.

According to one illustrative embodiment disclosed herein, a method for forming an interconnection structure in a substrate of a microstructure comprises forming a seed layer for initializing a subsequent electrochemical deposition process and forming a protection layer over the seed layer.

According to another illustrative embodiment, a method for forming a conductive structure comprises forming a conductive layer in a deposition tool and oxidizing a portion of the conductive layer inside the same deposition tool prior to moving the conductive structure from the deposition tool to subsequent processing tools.

According to a further illustrative embodiment, a method for forming a damascene structure of a semiconductor device comprises forming a conductive layer and forming, in an oxygen (O₂) rich atmosphere, a protection layer on the conductive layer.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1c schematically show cross-sectional views of a semiconductor device including an interconnection or a via structure at different stages during the fabrication process according to prior art processing methods;

FIG. 2 schematically represents a process flow for forming the interconnection or a via structure described in FIGS. 1a, 1c and 1d;

FIGS. 3a-3d schematically represent cross-sectional views of a semiconductor device including an interconnection or a via structure at different stages during the fabrication process according to the present disclosure; and

FIG. 4 schematically represents an illustrative process flow described herein.

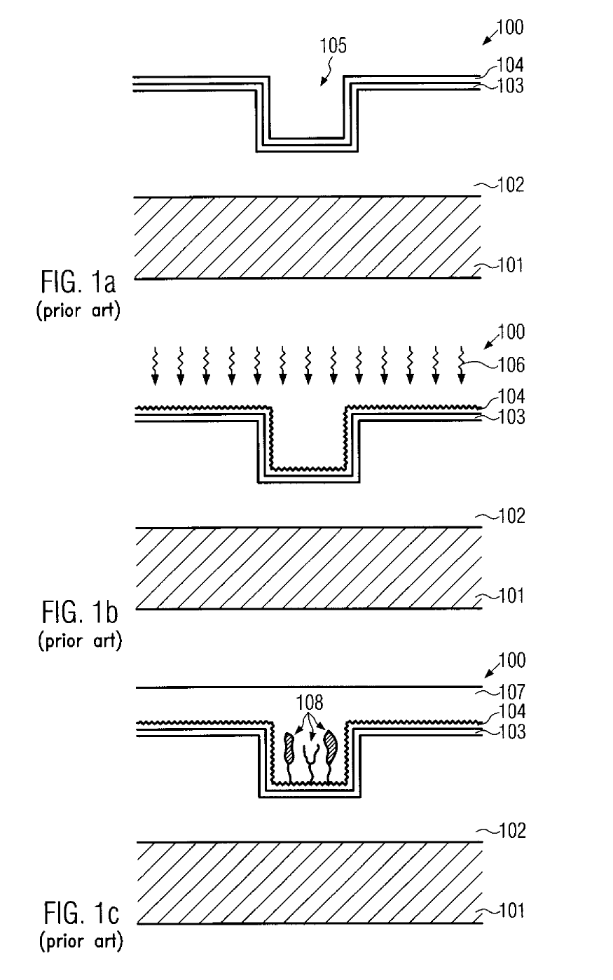

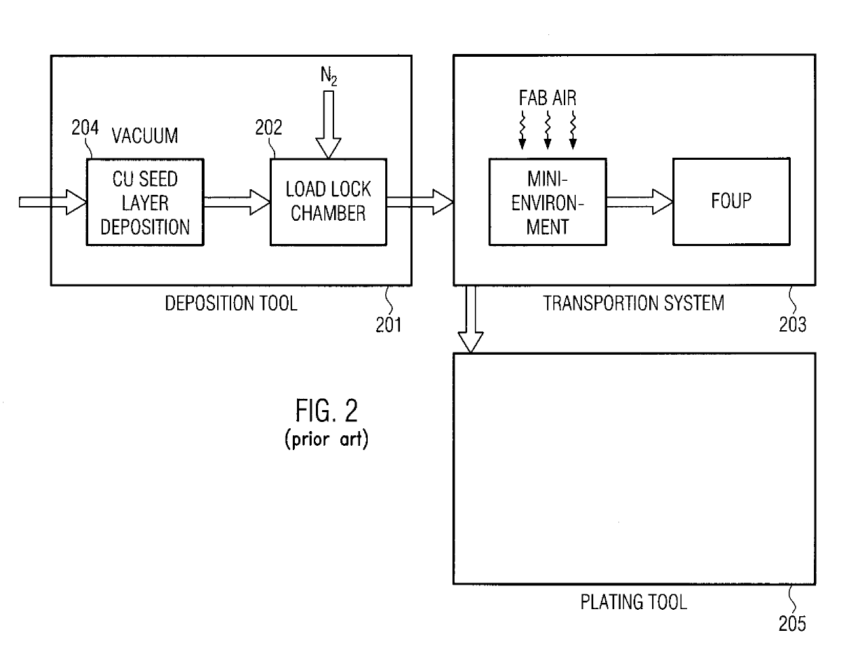

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure contemplates a technique that addresses the problems of surface contamination of exposed metal regions during the formation of vias, interconnections or the like in a dielectric layer, which may lead to a reduced reliability and yield, especially when semiconductor devices are considered that are fabricated on the basis of copper or copper compounds and copper alloys. As previously explained, oxygen, humidity, sulfur or other elements, which are present in the ambient air, may react with the exposed metal or copper surface, thereby generating a plurality of surface defects, which may lead to significant irregularities during the further processing of the semiconductor devices. This is particularly the case, for example, for the seed layer in an interconnection/via structure, which may comprise copper, copper alloys or copper compounds. According to the present disclosure, the generation of surface defects on the exposed surface, which can cause further defects during the subsequent processing of the semiconductor structure, may be reduced by a protection layer formed on the metal surface prior to exposure to the ambient air in the clean room.

In some illustrative embodiments, the protection layer is an oxide layer, typically a copper oxide layer, which is formed inside the deposition tool. This oxide layer can be formed in the load lock chamber, where, instead of an inert ambient, such as a nitrogen (N₂) rich atmosphere, an oxygen (O₂) rich atmosphere or any other highly oxidizing ambient is provided. According to some illustrative embodiments, the oxide layer formation may also be performed in a separated chamber located between the deposition chamber and the load lock chamber. The protection layer can efficiently block or substantially reduce any surface contamination which may take place when the semiconductor structure is exposed to the ambient air in the clean room during the transportation between different process tools, for example, a deposition tool and an electroplating tool. Once the semiconductor structure has arrived in the subsequent process tool, the protection layer can be removed using well-known etch processes, such as well-established wet chemical solutions, thereby exposing the surface of the seed layer in a substantially homogenous fashion, resulting in enhanced process uniformity of subsequent processes.

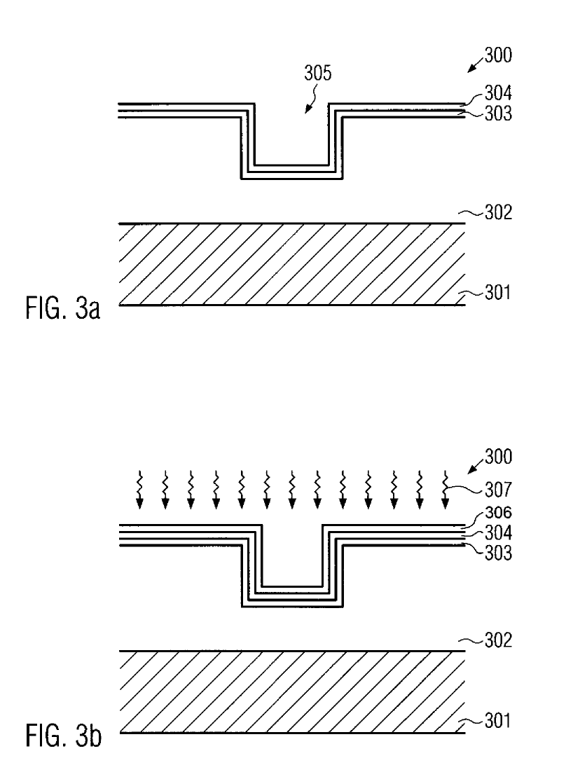

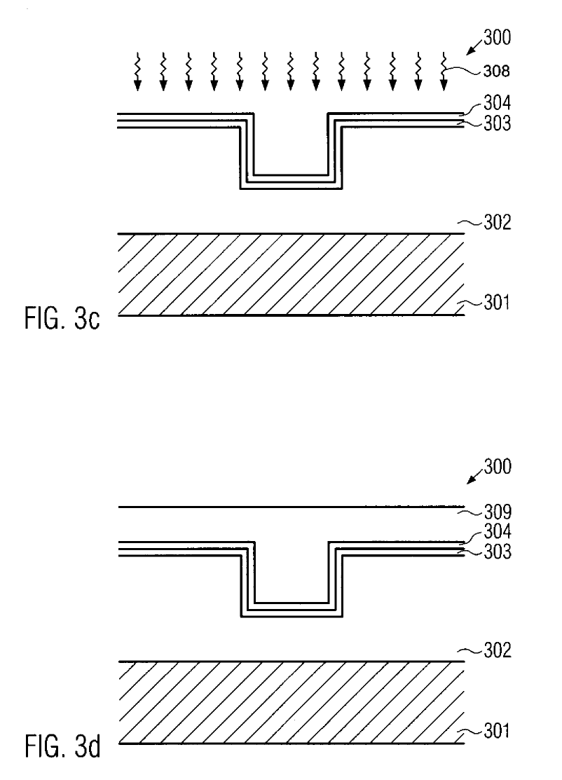

In FIG. 3a, a semiconductor device 300 is illustrated and is to represent any appropriate device that receives metal-filled features having dimensions as are typical for micro-structures. In the present embodiment, the semiconductor device 300 may represent an integrated circuit including a plurality of circuit elements, such as transistors, capacitors, resistors and the like, wherein at least some of these circuit elements may have critical dimensions of approximately 50 nm and even less. For convenience, any such circuit elements are not shown in FIG. 3a. Moreover, the semiconductor device 300 comprises a substrate 301 having formed thereon a first layer, such as a dielectric layer indicated as 302, which may contain an opening or a trench 305 in order to form an interconnect structure. The dielectric layer 302 may comprise any appropriate material, such as silicon dioxide, silicon nitride, or any low-k material, such as SiCOH, or any other material, such as appropriate polymers. The interconnect or via structure represented by the opening 305 may be filled with a metal comprising copper, a copper alloy, silver or any other appropriate conductive material as is typically used in semiconductor devices. The opening 305 may be covered by a barrier layer 303 and a seed layer 304. The barrier layer 303 may be comprised of any appropriate material, such as tantalum, tantalum nitride, titanium, titanium nitride, tungsten, tungsten nitride or any other appropriate material having the desired characteristics with respect to endowing the metal to be filled into the opening 305 with the required mechanical and chemical integrity. In some illustrative embodiments, the barrier layer 303 may be formed of one or more of the following compounds: cobalt, tungsten, phosphorous (CoWP) and/or cobalt, tungsten boron (COWB) and/or cobalt, boron (CoB) and/or molybdenum, nickel, boron (MoNiB), and the like.

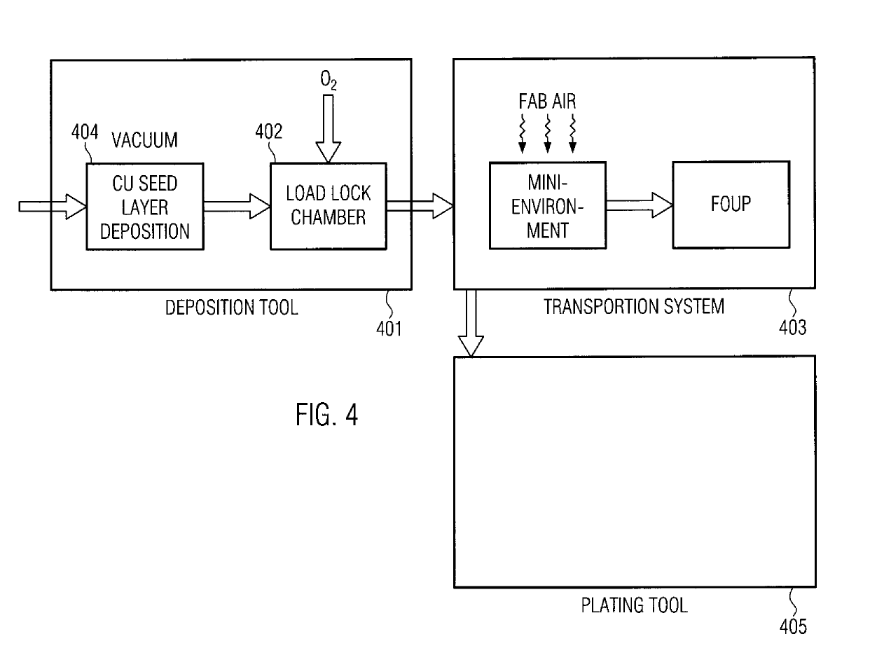

A typical process flow for forming the semiconductor device 300 is explained by also referring to FIG. 4. The layer 302 may be formed on the basis of well-established techniques, followed by a patterning sequence for forming the opening 305. Thereafter, the barrier layer 303 may be deposited by appropriate techniques. Then, the seed layer 304 may be formed in a vacuum chamber 404 inside a deposition tool 401, when deposition techniques such as PVD or CVD are used. In other cases, the layer 304 may be formed by electroless plating. When the deposition of the seed layer 304 is completed, the semiconductor device 300 is moved to a load lock chamber 402. In the load lock chamber 402, the semiconductor device 300 is exposed to a controlled oxidizing ambient, which in one illustrative embodiment may be established by an oxygen (O₂) rich atmosphere.

In FIG. 3b, the oxidation process is schematically depicted which takes place in the load lock chamber 402. An oxidizing ambient 307 created on the basis of an oxidizing species, such as oxygen (O₂) rich atmosphere, generates an oxide protection layer 306 on the seed layer 304. The oxidation process takes place under controlled conditions so that the final oxidation protection layer 306 may continuously cover the seed layer 304, thereby efficiently “passivating” the seed layer 304. The thickness may correspond to a predefined value and may be substantially constant across the layer protection 306. For example, the thickness may range from approximately 1 nm to several nm. Due to the controlled atmosphere under which the oxidation process takes place, the oxide protection layer has a high degree of purity, with only traces of other components. In a further embodiment, the oxidation process 307 may take place in a separated chamber not shown in FIG. 4 located between the deposition chamber 404 and the load lock chamber 402. In this case, a high degree of freedom in selecting respective oxidants may be provided, since the oxidizing ambient may be established without having to consider environmental restrictions imposed by the load lock chamber 402. In this case, even wet chemical oxidants may be used.

As shown in FIG. 4, after the formation of the oxidation protection layer 306 inside the deposition tool 401, the semiconductor structure 300 may come into contact with the external environment within the clean room and may be transported to the next process tool. The transportation system can comprise FOUP (Front Opening Unified Pod) boxes, or any other transport containers, wherein any constraints with respect to the exposure of the seed layer 304 to reactive components are significantly relaxed due to the provision of the protection layer 306. The protection layer 306 may be removed just before the subsequent fabrication process. In a particular embodiment, the subsequent process tool may be an electroplating tool 405, as shown in FIG. 4, in order to fill the opening 305 with conductive material.

The protection layer 306 may be removed using a well-known etch and cleaning process 308, as shown in FIG. 3c. Since the oxide layer 306 may be continuous with a predefined thickness range, the process 308 may exhibit a high degree of uniformity. Thus, contrary to the conventional strategies where the seed layer 304 is directly exposed to the external atmosphere in the clean room, generating uncontrolled oxide structures with different thickness on the seed layer 304, the further processing of the structure 300 may be continued on the basis of the seed layer 304 exposed during the highly uniform removal process 308, resulting in superior surface characteristics.

FIG. 3d schematically depicts the semiconductor device 300 after filling the opening 305 by electroplating, thereby forming a metal layer 309. The quality of the layer 309 is significantly improved with respect to the state of art, reducing the presence of voids or dislocations, which may deteriorate the conductivity and reliability of the device 300.

In a further embodiment, the protection layer 306 may be made of a material other than oxide, but which can still protect the seed layer 304 of the semiconductor structure 300. For example, materials may be used that may be removed by etch processes or heating and the like.

In other embodiments, more than one protective layer 306 may be provided above the seed layer 304 if enhanced degree of passivation may be required. For example, a first protective layer formed on the seed layer 304 may be an oxide layer followed by a second protective layer disposed on the oxide layer. The second layer may be easily removable by, for instance, heating the structure.

In a particular example, the conductive layer 309 is made of copper and the protective layer 306 is a copper oxide layer.

The method described herein may substantially avoid external contamination of single and dual damascene structures or other more complex structures where a metal layer comes into contact with the external atmosphere within the clean room.

It should further be appreciated that the seed layer 304 described in the previous embodiments may represent, in other embodiments, any other conductive layer requiring enhanced surface characteristics during the further processing.

The method disclosed herein provides improvement in terms of conductivity and reliability of interconnect structures in a semiconductor device. The formation of a continuous protection layer which may cover the conductive layer, such as a seed layer, may avoid uncontrolled contamination of the conductive layer by reactive components, such as oxygen, which would generate a rough and irregular surface on the conductive layer. Furthermore, in some illustrative embodiments, the formation of the protection layer may be performed with a high degree of compatibility to conventional process flows, since the conductive layer may be exposed to an oxidizing ambient at any appropriate point of the process flow after the deposition of the conductive layer, wherein, in some illustrative embodiments, the load lock chamber may be used for establishing the oxidizing ambient.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a seed layer for an interconnect structure in a substrate of a microstructure device; and
performing an oxidation process to form a sacrificial protection layer over said seed layer.

2. The method of claim 1, wherein said seed layer comprises copper (Cu).

3. The method of claim 1, wherein said protection layer is a continuous oxide layer.

4. The method of claim 1, wherein said interconnect structure is formed by a damascene process.

5. The method of claim 1, wherein said protection layer prevents contamination or corrosion of said seed layer.

6. The method of claim 1, wherein said seed layer and said protection layer are formed in the same deposition tool.

7. The method of claim 6, wherein said protection layer is formed in a load lock chamber of said deposition tool and said seed layer is formed in the deposition chamber of said deposition tool.

8. The method of claim 7, wherein said protection layer is formed in a separated chamber between the deposition chamber and the load lock chamber.

9. The method of claim 6, wherein said protection layer is formed in an oxidizing ambient.

10. The method of claim 9, wherein said oxidizing ambient is established as an oxygen rich atmosphere.

11. The method of claim 1, wherein said protection layer continuously covers said seed layer.

12. The method of claim 11, wherein said protection layer is removed inside said subsequent processing tool.

13. A method for forming a conductive structure, comprising:
forming a conductive layer in a deposition tool; and
oxidizing a portion of said conductive layer inside said deposition tool prior to moving the conductive structure from the deposition tool to subsequent processing tools.

14. The method of claim 13, wherein said conductive structure is a damascene structure.

15. The method of claim 13, wherein said conductive layer is a seed layer comprising copper (Cu).

16. The method of claim 13, wherein one of said subsequent processing tools is an electroplating tool.

17. The method of claim 13, wherein said oxidized portion of conductive material continuously covers said seed layer.

18. A method for forming a damascene structure of a semiconductor device comprising:
forming a conductive layer; and
forming in an oxygen rich atmosphere a protection layer on said conductive layer.

19. The method of claim 18, wherein said conductive layer is a seed layer comprising copper.

20. The method of claim 18, wherein said conductive layer and said protection layer are formed in the same deposition tool.
